(19) United States
(12) Patent Application Publication
(10) Pub. No.: US 2014/0001116 A1
(43) Pub. Date: Jan. 2, 2014

(54) MICROFLUIDIC EXTRACTION DEVICE HAVING A STABILIZED LIQUID/LIQUID INTERFACE

(71) Applicants: Jean Berthier, Meylan (FR); Nicolas Sarrut-Rio, Seyssins (FR)

(72) Inventors: Jean Berthier, Meylan (FR); Nicolas Sarrut-Rio, Seyssins (FR)

(73) Assignee: Commissariat a l'energie atomique et aux ene alt, Paris (FR)

(21) Appl. No.: 14/001,425

(22) PCT Filed: Feb. 24, 2012
(86) PCT No.: PCT/EP12/53159

§ 371 Date: Aug. 23, 2013

(30) Foreign Application Priority Data
Feb. 25, 2011 (FR) 1151571

(51) Int. Cl. B01D 11/04; B81B 1/00

(52) U.S. Cl. CPC B01D 11/0496; B81B 1/00
USPC 210/511

(57) ABSTRACT

A microfluidic device for extraction of analytes of interest from a carrier liquid in a liquid solvent, the two liquids forming an interface between micro-pillars in an extraction chamber. The carrier liquid forms a wetting angle θ1 on the micro-pillars and a bottom wall of the extraction chamber, and a wetting angle θ2 on a top wall, the wetting angles satisfying equation 45°≦(θ1+θ2)/2≦135°.

### TECHNICAL DOMAIN

This invention concerns the general domain of microfluidics and applies to cover a microfluidic device for liquid-liquid extraction of analytes of interest.

Analytes of interest are extracted in an extraction chamber of the micro-device, chamber in which the two liquids circulate, separated from each other by micro-pillars placed parallel to the flows.

The analytes of interest may be chemical and/or biological particles such as macromolecules, cells, organites, pathogens or even intercalators.

The microfluidic extraction device has applications particularly in biotechnologies, chemistry and environmental sciences.

### STATE OF PRIOR ART

Liquid samples need to be analysed in many industrial fields, particularly in order to determine the concentration of analytes that they may contain.

For example, this is the case for diagnostic, monitoring food processing or surveillance of the environment.

Analysis steps may require that said analytes of interest are transferred from a carrier liquid to a liquid solvent to obtain a high concentration of analytes in the liquid solvent, before the analytes are detected and their concentration is measured. This increases the efficiency and precision of detection of said analytes using standard analysis means.

It is known that this can be done using a liquid-liquid microfluidic extraction device, for example like that described particularly in the article by Berthier et al. entitled “The physics of a coflow micro-extractor: Interface stability and optimal extraction length”, 2009, Sensor. Actuator. A 149, 56-64.

As can be seen in FIGS. 1 and 2, such a micro-extractor 1 comprises an extraction chamber 30 formed by two transfer zones 31A, 31B separated from each other in the longitudinal direction by a plurality of micro-pillars 32. The longitudinal direction is the same as the flow direction of the liquids in the extraction chamber. It is the direction along which the interface between the two liquids extends.

The extraction chamber 30 is delimited by bottom, top and side walls. The micro-pillars 32 are aligned along the longitudinal direction and each extends between the bottom and the top walls.

Each transfer zone 31A, 31B communicates with a microchannel 40A, 40B which ensures fluidic circulation of the two liquids in the extraction chamber 30 along the longitudinal direction of the extraction chamber.

The carrier liquid P carrying analytes of interest circulates in the first transfer zone 31A, and the liquid solvent S circulates in the second transfer zone 31B.

According to the article mentioned above, the carrier liquid P is water or an aqueous solution, and the liquid solvent S is an organic solution. The two liquids are immiscible with each other.

The analytes of interest may be chemical and/or biological particles such as macromolecules, cells, organites, pathogens or even intercalators.

The interface of the carrier liquid P with the liquid solvent S is located between each micro-pillar 32 and extends between the bottom and top walls. More precisely, the carrier liquid P forms a plurality of interfaces with the liquid solvent S, each of which is in contact with two adjacent micro-pillars 32 and bottom and top walls.

The analytes of interest diffuse through the interfaces, from the carrier liquid to the liquid solvent, and bind for example to ligands such that they cannot return to the carrier liquid, or for example due to better solubility in the solvent.

However, operation of such a micro-extractor requires that the interfaces between the carrier liquid and the liquid solvent should be kept stable, in other words they should be kept in contact with the micro- pillars and the top and bottom walls during circulation of the liquids.

In particular, capillary wetting forces are applied to the interfaces due to contact of the fluids considered with the micro-pillars and said walls during their circulation.

It has been observed that the value of wetting angles of the carrier liquid on the material forming the micro-pillars and on the material forming the bottom and top walls, can have a predominant influence on the flow stability.

Thus, the interface is not stable when the wetting angle of a first liquid (for example the carrier liquid) with one of the materials forming the device (the top wall, the bottom wall or pillars) is too high (particularly more than 165° or even 170°). This causes said first liquid to invade the zone occupied by the second liquid (for example the solvent).

Therefore this break in the interface of the first liquid due to capillary wetting forces can cause severe degradation to the extraction efficiency of the micro-extractor, or even blockage of the device.

### PRESENTATION OF THE INVENTION

The purpose of the invention is to propose a microfluidic device for extraction of analytes of interest from a carrier liquid in a liquid solvent, in which the interface between the carrier liquid and the liquid solvent is more stable than it is in embodiments of prior art mentioned above.

The invention achieves this by proposing a microfluidic device for extraction of analytes of interest from an aqueous carrier liquid in a liquid solvent immiscible with the carrier liquid, comprising an extraction chamber delimited by bottom, top and side walls, and formed from a first and a second transfer zones forming a part of a first microchannel and of a second microchannel respectively, and being separated from each other along the longitudinal direction by a plurality of micro-pillars extending between said bottom and top walls, said device comprising means of forcing circulation of said carrier liquid with a non-zero flow D1 and of said liquid solvent with a non-zero flow D2 in said microchannels, where D1/D2>1, said first transfer zone containing said carrier liquid and said second transfer zone containing said liquid solvent, said liquid solvent forming a plurality of interfaces with said carrier liquid, each of which extends between two adjacent micro-pillars and said bottom and top walls, said device being characterised in that, said carrier liquid is immersed in the liquid solvent such that a first wetting angle θ1 is formed at the contact with a first material from which the micro-pillars and the bottom wall are made, and a second wetting angle θ2 is formed at the contact with a second material from which the top wall is made, said liquids and said materials are chosen so as to satisfy the following equation:

θ min≦(θ1+θ2)/2≦θmax

where θmin≧45° and θmax≦135°.

It can then be seen that the average of the wetting angles θ1 and θ2 defined above must be between the two limiting angles θₘᵢₙ and θₘₐₓ.

In general, it can be assumed that θ_{min≧}45° and θmax≦135°, which defines a first range within which the average of the wetting angles θ₁ and θ₂ can vary. A second more restricted and preferential range is defined between the limit angles θₘᵢₙ and θₘₐₓ such that θₘᵢₙ≧70° and θₘₐₓ≦110°.

The inventors observed that as a becomes closer to 0° (therefore when the average of the wetting angles θ₁ and θ₂ defined above approaches the limiting angles 45° or)135°, the pressure difference on each side of the interface has to be better controlled and must remain less than a critical pressure variation ΔPmax described later.

In other words, as the wetting angles of one of the two liquids with the material forming the pillars (θ₁) and the top wall (θ₂) become closer to the limit values of 45° or 135°, the equilibrium of the interface becomes more fragile and sensitive to the slightest fluctuation in the pressure difference on each side of the interface.

Preferably, the wetting angles θ₁ and θ₂ are more than 10° or even 15° and less than 170° or even 165°, to avoid the appearance of a contact film with one of the materials forming the device.

It is preferable if α is between 25° and 45°, in order to reduce the risks of the interface being unstable due to fluctuations in the pressure variation on each side of the interface. Thus, the wetting angles defined above remain within a restricted angular range for which the limiting values θₘᵢₙ and θₘₐₓ are such that θₘᵢₙ≧70° and θₘₐₓ≦120°.

For example, such a restricted angular range allows good stability of the interface, because it is relatively insensitive to pressure fluctuations on each side of the interface. For example, this range can be obtained by using the following materials and liquids:
first liquid: aqueous solution
second liquid: ionic liquid, for example [BMP],[NTf₂] (1-butyl-1 methylpyrrolidinium 2-(trifluoromethane sulfonamide).
material forming the pillars and the bottom wall: SiO₂
material forming the top wall: glass, for example Pyrex.

It will be understood that whenever possible, it is preferable if the average of the wetting angles θ₁ and θ₂ is as close to 90° as possible.

The carrier liquid is a liquid that contains analytes of interest.

The liquid solvent is a liquid that can receive and hold analytes of interest initially contained in the carrier liquid.

The longitudinal direction coincides with the direction along which the interface between the carrier liquid and the liquid solvent extends. When the carrier liquid and possibly the liquid solvent are flowing, the longitudinal direction coincides with the flow direction of the liquid(s). The longitudinal direction is contained in a plane approximately orthogonal to the bottom and top walls.

Advantageously, the widths w1, w2 of each of said transfer zones are chosen so as to satisfy the following relation:

$$\frac{{η}_{1} {D}_{1}}{{w}_{1}^{3}} ξ ( {α}_{1} ) = \frac{{η}_{2} {D}_{2}}{{w}_{2}^{3}} ξ ( {α}_{2} )$$

where ηᵢ is the dynamic viscosity of the liquid considered, and ξ(αᵢ) is a coefficient representing the friction applied to the liquid passing through the channel. This coefficient increases as the channel becomes narrower. This factor is usually between 1 and 5 for the target applications. In the case of a channel with a rectangular section, we have:

$$ξ ( {α}_{i} ) = \frac{1}{2 [ ( 1 / 3 ) - ( 64 {α}_{i} / {π}^{5} ) tan h ( π / 2 {α}_{i} ) ]}$$

$$where$$

$${α}_{i} = min ( \frac{{w}_{i}}{H} ; \frac{H}{{w}_{i}} ) ,$$

in which wᵢ is the width of channel i and H is the channel height, D₁ and D₂ are the carrier liquid and liquid solvent flows respectively.

Thus, the dynamic pressure difference between the carrier liquid and the liquid solvent in the extraction chamber is constant along the longitudinal direction of the extraction chamber. There is no risk that there is a zone in the extraction chamber in which the pressure difference exceeds a threshold value ΔPmax beyond which the interface might break. This threshold value can be the capillary pressure jump 2γ/δ, where γ is the surface tension of the liquid solvent in contact with the carrier liquid, and δ is the mean space between two adjacent micro-pillars. The result is an extraction chamber inside which the interfaces are stable at all points under normal pressure constraints. Therefore the extraction chamber can have a long working transfer length.

Advantageously, the microfluidic extraction device comprises means capable of imposing the static pressure of each of said liquids on the upstream or downstream side of the extraction chamber, said imposed static pressures being approximately equal to each other. In other words, it is advantageous if the pressure variation ΔP on each side of the interface is kept as close to 0 as possible, and in any case always less than the critical value ΔPmax.

Thus, the dynamic pressure difference between the two liquids at any one of said interfaces is approximately zero, and therefore is strictly less than the capillary threshold value 2γ/δ.

The microfluidic extraction device according to the invention can be made from two substrates. A bottom substrate and a top substrate, said micro-pillars and said bottom wall being formed within said bottom substrate while said top wall is formed by said top substrate.

Preferably, said bottom substrate is made from silicon oxide and said top substrate is made from glass.

Other advantages and characteristics of the invention will be mentioned in the non-limitative detailed description given below.

### BRIEF DESCRIPTION OF THE DRAWINGS

We will now describe some embodiments of the invention as non-limitative examples, with reference to the appended drawings, in which:

FIG. 1, already described, is a diagrammatic top view of a microfluidic extraction device according to an example of prior art;

FIG. 2, already described, is an enlarged and perspective view of part of the microfluidic extraction device shown in FIG. 1;

FIG. 3 is a representation of the wetting angle θ formed by a first wetting liquid L1 in a second liquid L2, at the contact with the surface of a material M;

FIG. 4 is a perspective diagrammatic view of the extraction chamber of a microfluidic extraction device according to the preferred embodiment of the invention;

FIG. 5 shows a cross-section through the microfluidic device of FIG. 4 when the stability condition is not satisfied.

### DETAILED PRESENTATION OF A PREFERRED EMBODIMENT

FIG. 4 shows a liquid-liquid microfluidic extraction device, or micro-extractor, capable of transferring analytes of interest from a carrier liquid to a liquid solvent according to the preferred embodiment of the invention.

It should be noted that the drawings are not to scale, to make them easier to read.

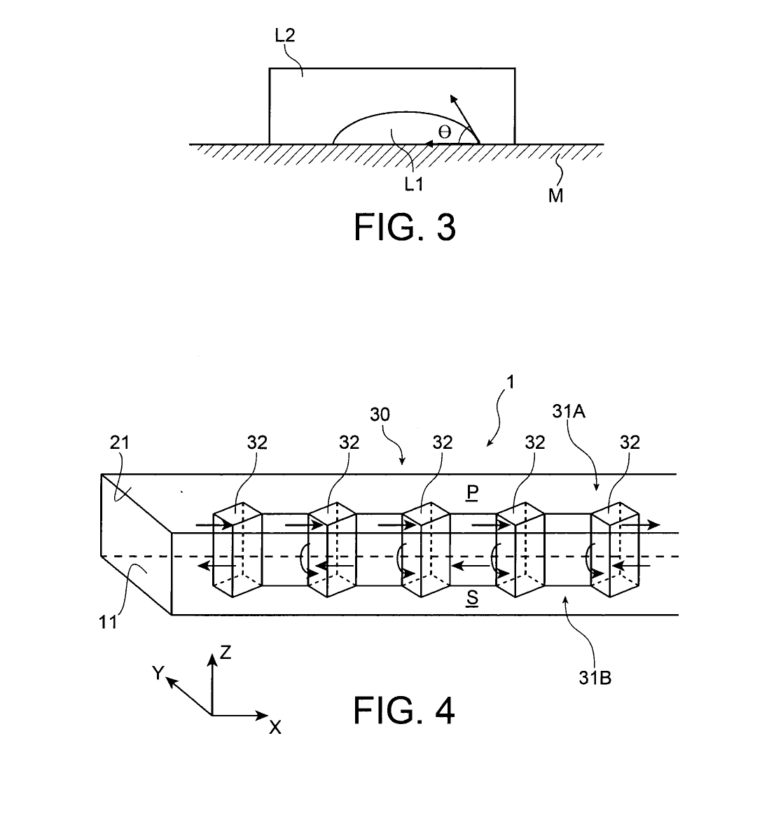

Throughout the following description, by convention, a direct Cartesian coordinate system (X,Y,Z) will be used as shown in FIG. 3. The X direction is the longitudinal direction along which liquid circulation takes place, the Y direction is orthogonal to the X direction and the Z direction is along the height of the device.

The terms <<bottom>> and <<top>> in this description refer to the orientation along the Z direction of said coordinate system.

The device 1 comprises an extraction chamber 30 delimited by the side walls, bottom wall 11 and top wall 12.

The extraction chamber 30 is formed from a first and a second transfer zones 31A, 31B separated from each other along the longitudinal direction by a plurality of micro-pillars 32.

The micro-pillars 32 are in line along the longitudinal direction and extend between said bottom wall 11 and top wall 21 along the Z direction.

They are preferably cylindrical in the general sense of the term, and may have a circular, oblong or even polygonal cross-section. Preferably, the section will be polygonal, for example triangular, square, rectangular and will have sharp corners.

Their average height H is defined by the distance between the bottom 11 and top 21 walls, and they have an average thickness e measured along the transverse direction.

The extraction chamber 30 is formed from a lower substrate and an upper substrate. The transfer zones 31A, 31B and the micro-pillars 32 are formed in the lower substrate. The upper substrate, or cover, is assembled to the lower substrate.

Thus the lateral walls, the bottom wall 11 and the micro-pillars 32 are made in the lower substrate, while the upper wall 21 is a face of the upper substrate.

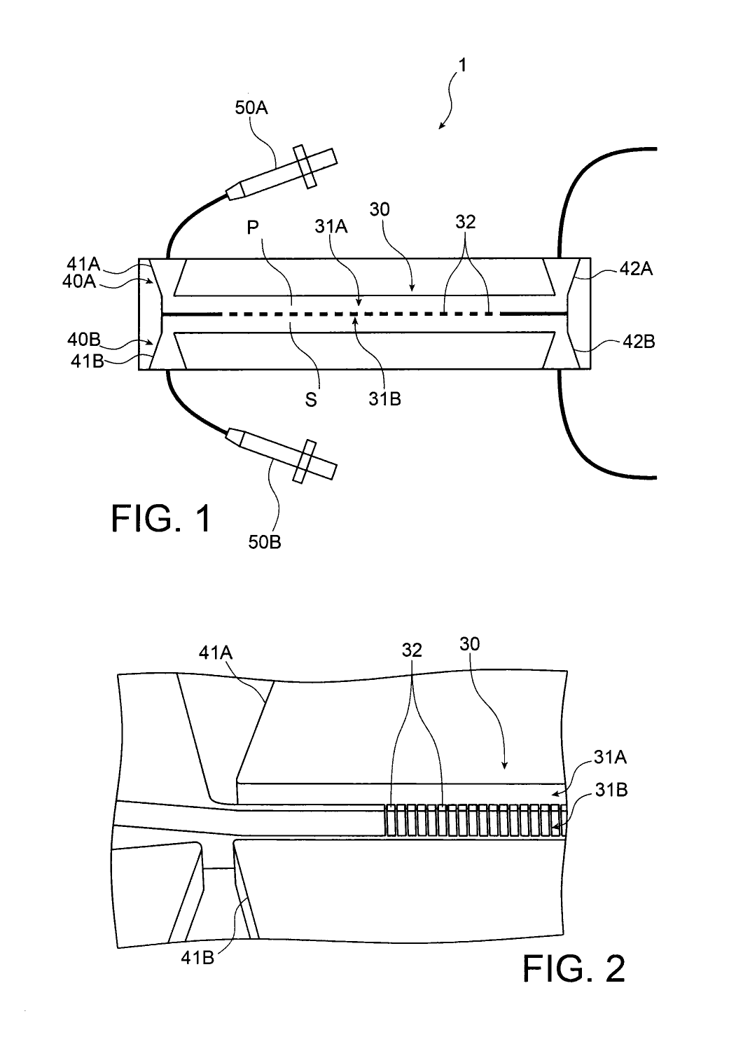

Each transfer zone 31A, 31B communicates with a microchannel 40A, 40B (not shown in FIG. 4) identical to that shown in FIG. 1. The microchannel 40A, 40B is formed from an inlet conduit 41A, 41B and an outlet conduit 42A, 42B located on the upstream and downstream sides respectively of the extraction chamber 30 (FIG. 1).

The first microchannel 40A is connected to means 50A of imposing circulation of a carrier liquid P carrying analytes of interest in the first transfer zone 31A at a non-zero flow D1. The second microchannel 40B is connected to means 50B of imposing circulation of a liquid solvent S in the second transfer zone 31B at a flow D2, which can be zero (FIG. 1).

It should be noted that the liquids P, S may circulate in co-flow or contra-flow.

The first transfer zone 31A contains the carrier liquid P and the second transfer zone 31B contains the liquid solvent S.

Advantageously, the liquid solvent S is ionic.

The carrier liquid P and the liquid solvent S together form a plurality of interfaces 2 in the extraction chamber 30, each of the interfaces extends between two adjacent micro-pillars 32 and between the bottom wall 11 and the top wall 21.

Wetting angles θ₁ and θ₂ on the materials from which the pillars and the bottom and top surfaces are made can be defined for each liquid considered, in fact the carrier liquid and the liquid solvent.

FIG. 3 illustrates particularly the definition of a wetting angle according to the invention. The wetting angle θ can be defined on this figure as being the contact angle that a drop of a first liquid L1 at rest immersed in a second liquid L2 at rest forms when it is placed in contact with a material M.

For the definition of wetting angles θ₁ and θ₂, it is assumed that the first liquid and the second liquid are at rest. The wetting angles thus defined are then characteristics of the materials from which the device is made (the top wall, the bottom wall or the pillars) and not of flows.

Considering a first liquid (for example the carrier liquid), a first wetting angle θ₁ can be defined corresponding to the contact angle that a drop of this first liquid immersed in the second liquid (the liquid solvent in this example) forms when it is placed in contact with the material from which the micro-pillars are made.

According to the invention, since the wetting angles are defined as a function of the liquids and materials, the wetting angle at the bottom wall 11 is approximately the same as the wetting angle measured at the micro-pillars 32. This angle will also be noted θ₁.

Indeed, the bottom wall and the micro-pillars are made from the same material, since they are made in the lower substrate.

A second wetting angle θ₂ is defined at the top wall 21; this is the contact angle that a drop of the first liquid immersed in the second liquid (the liquid solvent in this example) forms when it is placed in contact with the material from which the top wall is made.

It should be noted that the surfaces are said to be hydrophilic when the wetting angle 0 as shown in FIG. 3 is less than 90°, and hydrophobic if the angle θ is greater than 90°. It can be understood that the wetting angle 0 can represent the angle θ₁ in the case in which the material M is the material of the lower substrate, or θ₂ in the case in which the material M is the material of the upper substrate.

In the first case, in other words for θ less than 90°, the liquid considered is said to be wetting and in the second case it is said to be non-wetting. It should be noted that this is a case of partial wetting and not total wetting.

According to the invention, the carrier liquid P, the liquid solvent S and the materials of the micro-pillars and the top or bottom wall are chosen such that the wetting angles θ1 and θ2 satisfy the following relation:

45°≦(θ₁+θ₂)/2≦135°

Preferably, the wetting angles θ₁ and θ₂ are greater than 10° or even 15° and less than 170° or even 165° to avoid the development of a contact film with one of the materials forming the device (the top wall, the bottom wall or the pillars).

Thus, the interfaces 2 between two micro-pillars 32 are stable and remain in contact with the micro-pillars 32 and the top wall 11 and the bottom wall 21.

In other words, the following angles are defined at the interface between the micro-pillars and a material forming a top (or bottom) wall:

a first wetting angle θ₁ formed by a first liquid immersed in the second liquid, at the contact with the material from which the pillars and the bottom wall are made;

a second wetting angle θ₂ formed by said first liquid immersed in said second liquid, at the contact with the material from which the top wall is made;

the first liquid, the second liquid and the materials from which the micro-pillars, the bottom wall and the top wall are made, being chosen such that the stability condition is respected:

45°≦(θ₁+θ₂)/2≦135°

Thus, the average of the first and second wetting angles must be between two limiting angles θmin and θmax, where θmin 45° and θmax 135°.

Obviously, this condition must be applied to both the bottom wall and the top wall.

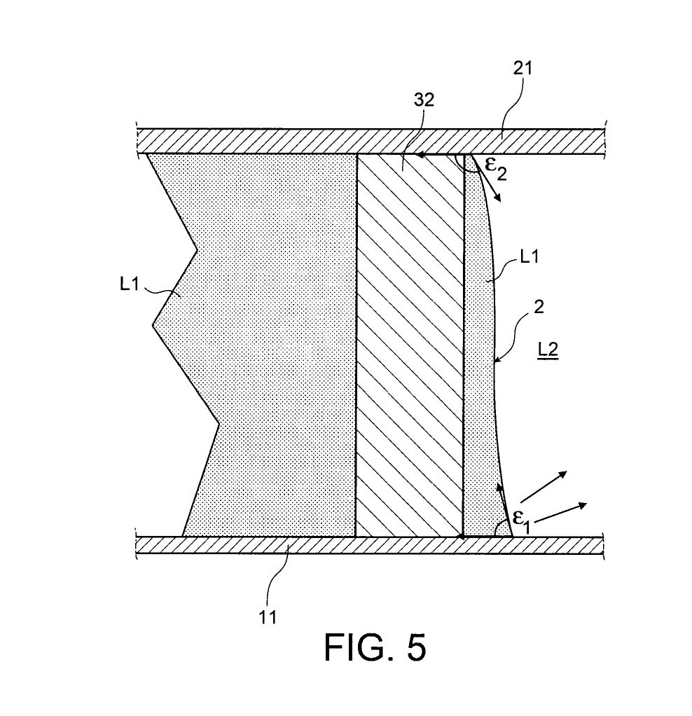

If this stability condition is not satisfied, the interface 2 moves along the arrows shown in bold in FIG. 5, which can lead to the interface breaking. In the example in FIG. 5, the first liquid L1 invades the half-channel reserved for L2. More precisely, FIG. 5 shows a cross-section of the microfluidic device in FIG. 4. In this case, the interface 2 has moved beyond the micro-pillar 32 and has entered the part of the micro-channel reserved for L2. The contact angles ε₁ and ε₂ that are shown are the result of flow conditions of liquids L₁ and L₂ in the device. They are not wetting angles (θ₁ or θ₂) as understood for the invention. Note that in this description, a wetting angle θ is defined as being the angle formed by a drop of a first liquid wetting a material M, this drop being immersed at rest in a second liquid.

The above-mentioned condition prevents the formation of a capillary-driven flow in a corner that occurs when the average of the angles θ1 and θ2 exceeds the lower or upper limits defined by the Concus-Finn condition. As demonstrated by Berthier and Silberzan in the book entitled Microfluidics for biotechnology, 2010, Artech House, an interface at the contact with an edge formed from two surfaces with different wettability defined by their wetting angles θ1 and θ2, remains at rest when the angles θ1 and θ2 satisfy the Concus-Finn condition:

π/2−α<(θ1+θ2)/2<π/2+α

where α is the half-angle of the corner. However, it is found that the interface 2 can be unstable when the average of the angles θ1 and θ2 is close to these limiting angles. Under these conditions, stability can only be achieved when the pressure variation ΔP on each side of the interface is less than the previously defined threshold ΔPmax. The slightest fluctuation in the pressure variation could cause an instability of the interface, that can cause invasion of the channel occupied by the least wetting liquid, by the most wetting liquid.

It has been observed that the interface 2 remains stable when the relation 70°(θ1+θ2)/2≦110° given above is satisfied. This reduced angular range is advantageous because it reduces the necessary control of the pressure variation on each side of the interface. Thus, minor fluctuations around ΔPmax are less likely to generate a break of the interface. Consequently, the system is more robust.

For example, when the micro-pillars 32 and the upper wall 21 are made of SiO2, the carrier liquid P being an aqueous solution and the solvent S being an organic solvent such as cyclohexane, the average of the angles θ1 and θ2 is 120°. However, although the result satisfies the Concus-Finn relation, a break in the interface is observed when the pressure on each side of the interface is not sufficiently well controlled.

On the other hand, when the solvent S is the ionic liquid BMP (1-butyl-1-methylpyrrolidinium), the angles θ1 and θ2 measured under the same conditions are 97° and 110° respectively, which gives an average of 103°. This average is within the restricted angular range 70°≦(θ1+θ2)/2≦110°. It has been observed that in this case the interface 2 is perfectly stable.

Moreover, the dynamic pressure of the carrier liquid P, and possibly that of the liquid solvent S, reduces progressively along the longitudinal direction of the extraction chamber 30.

It has been demonstrated in the article by Berthier et al. 2009 mentioned above, that the dynamic pressure difference between the carrier liquid P and the liquid solvent S along the longitudinal direction can exceed a threshold value beyond which the interface breaks.

This threshold value corresponds approximately to the capillary pressure jump 2γ/67 , where γ is the surface tension of the carrier liquid P in contact with the liquid solvent S, and δ is the average space between two adjacent micro-pillars 32.

In such a situation, there can be a length of the extraction chamber 30 beyond which the dynamic pressure difference reaches the threshold value. Therefore this critical length limits the working transfer length in the extraction chamber. To prevent this critical length phenomenon, the corresponding widths w1, w2 of said transfer zones 31A, 31B are chosen so as to satisfy the relation:

$$\frac{{η}_{1} {D}_{1}}{{w}_{1}^{3}} ξ ( {α}_{1} ) = \frac{{η}_{2} {D}_{2}}{{w}_{2}^{3}} ξ ( {α}_{2} )$$

where ηᵢ is the dynamic viscosity of the liquid considered, and ξ(αi) is a coefficient representing the friction applied to the liquid passing through the channel i. This coefficient increases as the channel becomes narrower. For the target applications, this factor is usually between 1 and 5. For a channel with a rectangular cross-section, we have:

$$ξ ( {α}_{i} ) = \frac{1}{2 [ ( 1 / 3 ) - ( 64 {α}_{i} / {π}^{5} ) tan h ( π / 2 {α}_{i} ) ]}$$

in which

$${α}_{i} = min ( \frac{{w}_{i}}{H} ; \frac{H}{{w}_{i}} )$$

as before, where wᵢ is the width of channel i and H is the channel height, D₁ and D₂ are the flows of the carrier liquid and the liquid solvent respectively.

Thus, the dynamic pressure difference between the carrier liquid P and the liquid solvent S in the extraction chamber 30 is constant along the longitudinal direction of the extraction chamber.

Therefore there is no longer a limit length at which the dynamic pressure difference reaches the capillary threshold value and makes the interface unstable.

An extraction chamber 30 is then obtained in which the interfaces 2 are stable at all points. The extraction chamber 30 can therefore be very long which can give a particularly large working transfer surface area.

It is also particularly advantageous if the static pressure in each of the liquids P, S is fixed on the upstream or downstream side of the extraction chamber 30, such that the imposed static pressures are approximately equal. Thus, since the pressure variation is zero on each side of the interface, the interface is very stable, particularly when 70°≦(θ1+θ2)/2≦110°.

Thus, the dynamic pressure difference between the two liquids P, S at either of said interfaces 2 is therefore approximately zero and is always strictly less than the capillary threshold value 2γ/δ.

The upstream or downstream static pressures may be fixed by means 50A, 50B adapted to impose circulation of the liquids in the microchannels, for example pumps for microfluidic flow (FIG. 1).

The micro-extractor 1 according to the preferred embodiment of the invention may be made as described below, and as partly described in the article by Tran et al entitled <<Micro-extractor for liquid-liquid extraction, concentration and in-situ detection of lead>> IMRET-10: 10th International Conference on Microreaction, AIchE 2008 Spring National Meeting, 6-10 April 2008, New Orleans, USA.

The lower substrate is monolithic and may be made of silicon (SiO₂). The upper substrate may be made of silicon or glass.

The microchannels 40A, 40B, the transfer zones 31A, 31B forming the extraction chamber 30 and the micro-pillars 32 can be made using conventional microtechnology techniques (for example photolithography followed by etching), for example by Deep Reactive Ion Etching (DRIE).

The DRIE etching method used for the lower substrate to make the transfer zones 31A, 31B and the micro-pillars 32 is identical to the etching method described in the article by Tran et al mentioned above.

The surfaces of the lower and upper substrates may be treated by silanisation, to modify the wetting angles θ1 and θ2 of the carrier liquid, if required.

The two substrates may be assembled using conventional molecular bonding techniques for silicon/silicon, or anodic bonding techniques for silicon/glass. They can also be assembled using a screen adhesive.

The height H of the extraction chamber 30 may be between 10 μm and 1 mm, and preferably between 50 μm and 500 μm. The length may be a few millimetres to a few centimetres, for example between 5 mm and 10 cm.

The width w1, w2 of the transfer zones 31A, 31B may be between 0.5 and 10 times the height H.

The micro-pillars 32 are practically identical to each other. Their height is equal to the height H of the extraction chamber 30. Their side length or the diagonal is between 0.02 and 1 times the height H. For example, the micro-pillars 32 may have a diameter or side dimension of 30 μm and a height of 100 μm.

The spacing between the micro-pillars 32 is preferably greater than 1 μm, for example from a few microns to a few tens of microns, preferably of the order of 5 to 10 μm.

Thus, the interface area 2 is the working transfer surface area, that can vary from a few square millimetres to a few tens of square millimetres.

The liquids P, S are immiscible with each other. The carrier liquid P is advantageously aqueous, for example water. The liquid solvent S is advantageously ionic, for example [BMP] [NTf2] (1-butyl-1-methylpyrrolidinium 2-(trifluoromethane sulfonamide)).

The two liquids P, S have flows D1 and D2 such that D1/D2 is more than 1 and preferably more than 10 and advantageously more than 100. The flow of the carrier liquid P may be between 1 and 10 μl/min, and the flow of the liquid solvent S may be between 0.01 and 5 μl/min.

The two liquids P, S are preferably chosen such that the average of the wetting angles θ1 and θ2 defined above satisfies the relation 70°≦(θ1+θ2)/2≦110°.

Liquids P and S are circulated by syringe pumps and/or electronic nanopumps like the Dionex Ultimate 3000.

Obviously, those skilled in the art could make various modifications to the invention as described above solely as non-limitative examples.

Thus, the description only contains details of the embodiment in which the side walls, the bottom wall 11 and the micro-pillars 32 are made from the same material forming the lower substrate, while the top wall 21 is a face of the upper substrate made from another material.

In this case, the first wetting angle θ₁ has been described as the angle formed by a first liquid immersed in a second liquid, at the contact with the material forming the pillars and the bottom wall, and the second wetting angle θ₂ as the angle formed by said first liquid immersed in said second liquid, at the contact with the material forming the top wall.

It will be understood that, without going outside the scope of this invention, in a first variant of the embodiment described, the side walls, the top wall 11 and the micro-pillars could be made from the same material forming the lower substrate, while the bottom wall is one face of the upper substrate made from another material.

According to this first variant, the first wetting angle θ₁ is the angle formed by a first liquid immersed in a second liquid, at the contact with the material from which the pillars and the top wall are made; and the second wetting angle θ₂ is the angle formed by said first liquid immersed in said second liquid, at the contact with the material from which the bottom wall is made.

In a second variant of the embodiment described, the bottom wall and the top wall can be made from the same material, and the pillars from another material.

According to this second variant, the first wetting angle θ₁ is the angle formed by a first liquid immersed in a second liquid, at the contact with the material from which the pillars are made; and the second wetting angle θ₂ is the angle formed by said first liquid immersed in said second liquid, at the contact with the material from which the bottom wall and the top wall are made.

1-9. (canceled)

10. A microfluidic device for extraction of analytes of interest from a carrier liquid in a liquid solvent immiscible with the carrier liquid, comprising:
an extraction chamber delimited by bottom, top, and side walls, and including a first and a second transfer zone forming a part of a first microchannel and of a second microchannel respectively, and being separated from each other along the longitudinal direction by a plurality of micro-pillars extending between the bottom wall and the top wall;
means for forcing circulation of the carrier liquid and the liquid solvent in the microchannels, the first transfer zone including the carrier liquid and the second transfer zone including the liquid solvent, the liquid solvent forming a plurality of interfaces with the carrier liquid, each of which extends between two adjacent micro-pillars and the bottom wall and the top wall,
wherein the carrier liquid is immersed in the liquid solvent and forms a first wetting angle θ1 at a contact with a first material from which the micro-pillars are made, and a second wetting angle θ2 at a contact with a second material from which the top wall or the bottom wall is made, the liquids and the materials satisfy equation:
θmin≦(θ1+θ2)/2≦θmax
wherein θmin ≧45° and θmax≦135°.

11. A microfluidic extraction device according to claim 10, wherein θmin≧70° and θmax≦110°.

12. A microfluidic extraction device according to claim 10, wherein the solvent is ionic.

13. A microfluidic extraction device according to claim 10, wherein the carrier liquid is aqueous.

14. A microfluidic extraction device according to claim 10, wherein the means for forcing circulation in the microchannels forces a circulation of the carrier liquid with a non-zero flow D1 and of the liquid solvent with a non-zero flow D2, wherein D1/D2>1.

15. A microfluidic extraction device according to claim 14, wherein widths w1, w2 of the transfer zones respectively satisfy equation
$$\frac{{η}_{1} {D}_{1}}{{w}_{1}^{3}} ξ ( {α}_{1} ) = \frac{{η}_{2} {D}_{2}}{{w}_{2}^{3}} ξ ( {α}_{2} ) ,$$
wherein ηᵢ is the dynamic viscosity of the liquid i considered, ξ(αᵢ) is a coefficient representing the friction applied to the liquid passing through the channel i , ξ(αᵢ) is between 1 and 5, and D₁, D₂ are the flows of the carrier liquid and the liquid solvent respectively.

16. A microfluidic extraction device according to claim 10, further comprising means for imposing static pressure of each of the liquids on an upstream or downstream side of the extraction chamber, the imposed static pressures being approximately equal to each other.

17. A microfluidic extraction device according to claim 10, further comprising a bottom substrate and a top substrate, the micro-pillars and the bottom wall being formed within the bottom substrate and the top wall being formed by the top substrate.

18. A microfluidic extraction device according to claim 17, wherein the bottom substrate is made from silicon oxide and the top substrate is made from glass.
